(19) United States
(12) Patent Application Publication
(10) Pub. No.: US 2025/0092517 A1
(43) Pub. Date: Mar. 20, 2025

(54) PRECURSOR CAPSULE, A VESSEL AND A METHOD

(71) Applicant: ASM IP Holding B.V., Almere (NL)

(72) Inventors: Chiyu Zhu, Helsinki (FI); Jaakko Anttila, Helsinki (FI)

(21) Appl. No.: 18/899,215

(22) Filed: Sep. 27, 2024

Related U.S. Application Data
(63) Continuation of application No. 17/554,253, filed on Dec. 17, 2021, now Pat. No. 12,129,545.
(60) Provisional application No. 63/129,359, filed on Dec. 22, 2020.

(51) Int. Cl. C23C 16/448

(52) U.S. Cl. CPC C23C 16/448

(57) ABSTRACT

The current disclosure relates to a precursor capsule for holding a precursor for a vapor deposition process. The precursor capsule comprises a vapor-permeable shell configured to define a precursor space, and to allow precursor in vapor form to leave the precursor capsule under vaporization conditions. The disclosure further relates to a precursor vessel comprising capsules according to the current disclosure, to a vapor deposition apparatus and a method.

### CROSS-REFERENCE TO RELATED APPLICATIONS

This application is a continuation of, and claims priority to, U.S. patent application Ser. No. 17/554,253 filed Dec. 17, 2021 titled PRECURSOR CAPSULE, A VESSEL AND A METHOD; which claims priority to U.S. Provisional Patent Application Ser. No. 63/129,359 filed Dec. 22, 2020 titled PRECURSOR CAPSULE, VESSEL AND METHOD, the disclosures of which are hereby incorporated by reference in their entirety.

### FIELD

The present disclosure relates generally to systems and methods involving semiconductor processing equipment, and specifically to vaporizing systems for chemical vapor delivery.

### BACKGROUND

A typical precursor, or source reactant, delivery system for vapor deposition processes includes a solid or liquid source vessel. The vessel can include a chemical reactant that is to be vaporized. A carrier gas sweeps reactant vapor along with it through a vessel outlet and ultimately to a substrate in a reaction chamber, or the precursor is vaporized at low pressure. The efficiency of vaporization partially depends on the precursor surface area exposed to the carrier gas. Thus, there are solutions in the art aiming at distributing the precursor composition more effectively in the precursor vessel or otherwise increasing the vaporization area. Further, process control may be challenging especially for solid precursors. In many instances, achieving high enough vaporization of the precursor requires heating the precursor above ambient temperature. Maintaining a solid precursor composition in elevated temperatures for extended periods of time may cause agglomeration of the precursor composition leading to the reduction of precursor surface area available for vaporization. This may lead to alterations in dose behavior of the precursor composition and consequently in the properties of the deposited material.

After a precursor has been depleted, the precursor vessel is refilled. In addition to stringent cleanness requirements, the handling of precursor compositions has to be compatible with moisture sensitivity, toxicity or other, possibly challenging, characteristics of precursor compositions. They may necessitate working in a tightly controlled environment. The filling of precursor vessels may thus be a slow and expensive task.

Therefore, there is a need in the art for a simplified method of packing a precursor into a precursor vessel for vapor deposition.

### SUMMARY

In a first aspect, a precursor capsule for holding a precursor for a vapor deposition process is disclosed. The precursor capsule according to the current disclosure comprises a shell configured to define a precursor space. The shell is vapor permeable to allow precursor in vapor form to leave the precursor capsule under vaporization conditions.

In a second aspect, a precursor vessel is disclosed. The precursor vessel contains at least two precursor capsules for holding a precursor for a vapor deposition process is, wherein the precursor capsules comprise a shell configured to define a precursor space, and wherein the shell is vapor permeable to allow precursor in vapor form to leave the precursor capsule under vaporization conditions.

In a third aspect, a vapor deposition assembly is disclosed. The vapor deposition assembly according to the current disclosure comprises a precursor vessel containing at least two precursor capsules for holding a precursor for a vapor deposition process, wherein the precursor capsules comprise a shell configured to define a precursor space, and wherein the shell is vapor permeable to allow precursor in vapor form to leave the precursor capsule under vaporization conditions.

In a fourth aspect, a method of loading a precursor into a precursor vessel is disclosed. The method comprises providing precursor capsules for holding a precursor for a vapor deposition process containing a precursor composition, and inserting at least two precursor capsules into the precursor vessel, wherein the precursor capsules comprise a shell configured to define a precursor space, and wherein the shell is vapor permeable to allow precursor in vapor form to leave the precursor capsule under vaporization conditions.

The precursor capsule, the precursor vessel, vapor deposition assembly and the method according to the current disclosure may have the advantage of increasing the surface area of a precursor available for vaporization in the absence of additional structures in the precursor vessel. Additionally, the effect of precursor agglomeration during the vessel on-tool time may be reduced. The precursor capsules may also offer a cost-effective alternative for filling precursor vessels. It may be possible to increase the throughput of refilling precursor vessels, since a precursor capsule may be pre-filled with precursor composition in advance, and capsules may be loaded into a precursor vessel more efficiently than composition as such. For example, a chemical supplier may sell a precursor pre-packed into a precursor capsule according to the current disclosure, and the customer may fill the vessel on-site, without the need to send the complete precursor vessel for filling. Further, for solid precursors comprising of powder or small granules, the landing of precursor composition in the sealing surfaces of the vessel may be reduced or avoided. Still further, the shell of a capsule may function as a particle filter for a solid precursor. An added advantage of a capsule according to the current disclosure may thus be that the amount of particle contamination from a powder-like precursor may be reduced. This may reduce or, in some embodiments, eliminate the need for additional particle filters downstream of the precursor vessel. Another advantage may be that the lifetime of a particle filter downstream of a precursor vessel containing precursor capsules according to the current disclosure may be extended.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIGS. 1A, 1B, and 1C illustrate embodiments of a chemical precursor vessel according to the current disclosure

FIG. 2 illustrates an embodiment of vapor deposition assembly according to the current disclosure.

FIG. 3, panels A to K, illustrates exemplary embodiments of a precursor capsule according to the current disclosure.

### DETAILED DESCRIPTION OF EXEMPLARY EMBODIMENTS

The description of embodiments of precursor capsules, vessels and methods provided below is merely exemplary and is intended for purposes of illustration only. The following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising” or “comprising”. In this disclosure, any defined meanings do not necessarily exclude ordinary and customary meanings in some embodiments.

The headings provided herein are for convenience only and do not necessarily affect the scope or meaning of the claimed invention. Described herein are systems and related methodologies for delivering vaporized or sublimed reactant in a high capacity deposition module.

A chemical reactant delivery system for vapor deposition can include a solid or liquid source vessel for providing a reactant into a reaction chamber. A source vessel (i.e. a precursor vessel or a precursor vessel) can include a housing for defining a vessel space inside the precursor vessel. The housing can comprise a lid and/or a fill port for precursor loading. The housing can include a fluid inlet and a fluid outlet for transferring fluids in and out of the precursor vessel, respectively. In some embodiments, the fluid inlet and/or fluid outlet are positioned in the lid.

The precursor capsule according to the current disclosure is designed to hold a precursor for a vapor deposition process. The precursor may be a liquid precursor or a solid precursor. The size, material and other properties of the precursor capsule are selected in a way that a capsule is compatible with a vapor deposition process. By a capsule is herein meant a casing or a small box into which a precursor may be loaded. The precursor may be present in a form of a precursor composition. A composition may be viewed a solid composition if it is solid at standard temperature and pressure, or in the deposition conditions. A composition may be viewed a liquid composition if it is liquid at standard temperature and pressure, or in the deposition conditions.

By a precursor composition is herein meant a preparation of a chemical that may be used for vapor deposition applications. Generally, compositions need to be stable enough for allowing the storage and use over an extended period of times, for example, over several weeks or even months. Additionally, the vaporization rate of a precursor compound under predetermined conditions remains preferably constant. A composition also needs to allow the vaporization of the precursor molecule so that it may be delivered to a deposition chamber for vapor deposition. Thus, the temperature and pressure ranges at which a precursor contained in the composition have to be suitable for vapor deposition.

The terms “precursor” and “reactant” are used interchangeably in the current disclosure, and can refer to molecules (compounds, or molecules comprising a single element) that participate in a chemical reaction that produces another compound. A precursor or a reactant typically contains portions that at least partly form the compound or element resulting from the chemical reaction in question. Such a resulting compound or element may be deposited on a substrate. However, a precursor or a reactant may be an element or a compound that is not incorporated into the resulting compound or element to a significant extent.

Examples of solid precursors that may be loaded into a precursor vessel according to the current disclosure are, for example, metal halides, such as HfCl₄, InI₃, FeCl₃, metal-organic precursors, organometallic precursors and organic precursors, such as pyromellitic dianhydride. Precursor capsules according to the current disclosure may find use especially for solid precursors where obtaining a practically high vapor pressure with conventional precursor vessels would require high vaporization temperatures, such as above 150° C. or 200° C. Examples of liquid precursors that may be loaded into a precursor vessel according to the current disclosure are, for example, metal-organic precursors or organometallic precursors having a relatively low vapor pressure. Generally, the advantages of the current disclosure may be most readily apparent for precursors having low vapor pressures in room temperature. In some embodiments, the shell is configured and arranged to hold a solid precursor. In some embodiments, the shell is configured and arranged to hold a liquid precursor.

A vapor deposition process according to the current disclosure may be a chemical vapor deposition (CVD) process. A vapor deposition process according to the current disclosure may be an atomic layer deposition (ALD) process. A vapor deposition process according to the current disclosure may be a cyclic vapor deposition process. As used herein, the term “cyclic deposition” may refer to the sequential introduction of precursors (reactants) into a reaction chamber to deposit a layer over a substrate, and includes processing techniques such as atomic layer deposition and cyclical chemical vapor position. Vapor deposition may be used, for example, in the manufacture of semiconductor devices in electronics industry. Thin films may be deposited on substrate by vapor deposition. As used herein, the term “substrate” can refer to any underlying material or materials that can be used to form, or upon which, a structure, a device, a circuit, or a layer can be formed.

CVD-type processes typically involve gas phase reactions between two or more precursors or reactants. The precursors or reactants can be provided simultaneously to the reaction chamber or substrate, or in partially or completely separated pulses. The substrate and/or reaction space can be heated to promote the reaction between the gaseous reactants. In some embodiments the reactants are provided until a thin film having a desired thickness is deposited. Thus, a CVD-type process may be a cyclical process or a non-cyclical process. In some embodiments, cyclical CVD-type processes can be used with multiple cycles to deposit a thin film having a desired thickness. In cyclical CVD-type processes, the reactants may be provided to the reaction chamber in pulses that do not overlap, or that partially or completely overlap.

ALD-type processes are based on controlled, typically self-limiting surface reactions of the precursor and/or reactant chemicals. Gas phase reactions are avoided by feeding the precursors alternately and sequentially into the reaction chamber. Vapor phase reactants are separated from each other in the reaction chamber, for example, by removing excess reactants and/or reactant by-products from the reaction chamber between reactant pulses. This may be accomplished with an evacuation step and/or with an inactive gas pulse or purge. In some embodiments the substrate is contacted with a purge gas, such as an inactive gas. For example, the substrate may be contacted with a purge gas between reactant pulses to remove excess reactant and reaction by-products. In some embodiments each reaction is self-limiting and monolayer by monolayer growth is achieved. These may be referred to as “true ALD” reactions. In some such embodiments a first precursor may adsorb on the substrate surface in a self-limiting manner. A second precursor or a reactant, and optional further reactants or precursors will react in turn with the first adsorbed precursor to form up to a monolayer of metal or metal compound on the substrate.

In some embodiments, a precursor capsule according to the current disclosure is configured to be loadable in a precursor vessel for performing a vapor deposition process. Thus, the material, size, structural details and other features of the precursor capsule may be selected so that the precursor capsule may be loaded into a precursor vessel. Additionally, the precursor capsule according to the current disclosure is adapted to be used in a vapor deposition process. Since vapor deposition processes are sensitive to contamination and to other changes in process conditions, the properties of a precursor capsule may be selected as to provide as reproducible results as possible, as well as for being sufficiently inert not to introduce unwanted changes in the vapor composition of process gases.

A plurality (i.e. two or more) of precursor capsules according to the current disclosure may be filled with a precursor, and loaded into a precursor vessel. The size and shape of a capsule is selected so that a sufficient number of precursor capsules may be loaded into a precursor vessel. Generally, it may be advantageous to load many small precursor capsules into a precursor vessel to obtain the advantages of the current disclosure to a larger extent. In some embodiments, precursor capsules according to the current disclosure are separate units. In some embodiments, at least two precursor capsules according to the current disclosure are attached to each other. In some embodiments, at least five precursor capsules according to the current disclosure are attached to each other. In some embodiments, at least ten precursor capsules according to the current disclosure are attached to each other. In some embodiments, precursor capsules are attached to each other by a flexible attachment.

The precursor capsule separates a precursor into smaller units. One of the advantages of the current invention is that the surface area available for vaporization may be increased relative to simply loading the precursor into the reaction vessel directly. At the same time, the reaction vessel structure can remain simple, since a precursor capsule according to the current disclosure may be used without designing any internal structures in the precursor vessel. Thus, the current precursor capsule may increase the vaporization efficiency of basic precursor vessels, and possibly broaden their usability to precursors that are more difficult to vaporize. Thus, a basic vessel may be utilized for a more demanding processes.

An advantage of the current disclosure may further relate to the precursor or precursor composition behavior during the on-tool time of the precursor vessel. The precursors are often heated to bring about sufficient vaporization of the precursor. Without limiting the current invention to any specific theory, a solid precursor may agglomerate or “cake” during extended periods of time in elevated temperatures. The precursor may be packed more tightly, and lose its original powdery or granular structure, leading into decrease in surface area and lower vaporization rate. The same phenomenon may take place in a precursor capsule, but the decrease in precursor surface area may be reduced compared to the solid precursor being present as a continuous mass.

The number of the precursor capsules loaded into a precursor vessel varies according to the application in question. For example, a capsule according to the current disclosure may be used in experimental set-ups or for testing a new precursor or precursor composition. In such a case, a smaller number of capsules or a smaller precursor vessel may be used. However, a precursor capsule according to the current disclosure may also be used in higher-volume applications. For example, the improvement in vaporization efficiency may allow the use of a cheaper precursor or a precursor composition, if the vaporization efficiency has been limiting the use of such precursors. Alternatively, costs savings may be achieved through the use of the current precursor capsule in combination with less sophisticated precursor vessels, and thus avoiding the use of pricier specialty vessels. In some embodiments, at least five precursor capsules may be packed in a precursor vessel. In some embodiments, at least eight precursor capsules may be packed in a precursor vessel. In some embodiments, at least ten precursor capsules may be packed in a precursor vessel. In some embodiments, at least 15 precursor capsules may be packed in a precursor vessel. In some embodiments, at least 20 precursor capsules may be packed in a precursor vessel. In some embodiments, at least 25 precursor capsules may be packed in a precursor vessel. In some embodiments, at least 30 precursor capsules may be packed in a precursor vessel. In some embodiments, at least 50 precursor capsules may be packed in a precursor vessel. In some embodiments, at least 70 precursor capsules may be packed in a precursor vessel. In some embodiments, at least 100 precursor capsules may be packed in a precursor vessel. In some embodiments, at least 500 precursor capsules may be packed in a precursor vessel. There is no fixed upper limit for the number of precursor capsules that may be packed in a precursor vessel, as the number depends on the size of both the capsules and the vessel, as well as on the amount of precursor loaded into the vessel. For example, in some embodiments, up to several kilograms of precursor composition may be loaded into a precursor vessel. Even in such large-scale applications, each capsule may contain a precursor in the range of grams or tens of grams. Thus, In some embodiments, at least 1,000 precursor capsules may be packed in a precursor vessel. In some embodiments, at least 2,000 precursor capsules may be packed in a precursor vessel.

The precursor capsule according to the current disclosure comprises a shell defining a precursor space. The shell of a precursor capsule according to the current disclosure substantially rigid. By rigid is herein meant self-supporting. In other words, a capsule can keep its shape under conditions existing in a precursor vessel. Since a precursor capsule according to the current disclosure is designed to be loadable into a precursor vessel, the shell needs to be rigid enough to withstand the weight of other precursor-filled capsules that may be placed on it. A precursor capsule may be flexible. Especially in embodiments in which the precursor capsule is oblong or tube-like, it may be beneficial to design a bendable precursor capsule to improve packing efficiency of the capsules into the precursor vessel.

The shell defines the shape of a precursor capsule. It may be advantageous to maximize the surface area of a precursor capsule relative to the volume of precursor. In some embodiments, the shell may be substantially spherical. It may also be advantageous for the precursor capsule to have shape that allows precursor capsules to be packed loosely, to allow gas flow between capsules. Thus, it may be advantageous for the shell to be at least partly curved. In some embodiments, the shell comprises curved surfaces. In some embodiments, the shell has an ellipsoid shape.

In some embodiments, the shell (i.e. the precursor capsule) has a width and a length. The width of a capsule may be considered the smallest measurement of the shell, and its length the largest measurement of the shell perpendicular to the width. The shell of a precursor capsule according to the current disclosure may have a tubular shape. The shell can be considered tubular, if its length is more than three times its width. In some embodiments, the shell has substantially spherocylindrical shape. A spherocylindical shape is a circular cylinder with substantially hemispherical ends. For the purposes of the current disclosure, the ends of a spherocylindical shell do not need to be full hemispheres, but it suffices for them to comprise some spherical surface. In some embodiments, the shell has a substantially a cylindrical shape. The ends of a cylinder are substantially flat.

In some embodiments, the shell has a width and a length, and the width to length ratio of the shell is from about 1:1 to about 1:20. For example, the width to length ratio of a capsule is from about 1:2 to about 1:20, or from about 1:3 to about 1:20, or from about 1:5 to about 1:20, or from about 1:7 to about 1:20, or from about 1:10 to about 1:20, or from about 1:2 to about 1:10, or from about 1:5 to 1:10. In some embodiments, the width to length ratio of a capsule is from about 1:1 to about 1:10, or from about 1:1 to about 1:6, or from about 1:1 to about 1:5, or from about 1:1 to about 1:4, or from about 1:1 to about 1:3, or from about 1:1 to about 1:2.

The shell of a precursor capsule defines a precursor space. Thus, a capsule according to the current disclosure is hollow and a precursor or a precursor composition may be filled into the hollow interior of the precursor capsule. To maximize gas flow between the interior and the exterior of the shell, the shell may be as thin as possible without compromising its rigidity. In some embodiments, the thickness of the shell is from about 0.1 mm to about 1 mm, such as about 0.25 mm, about 0.4 mm, about 0.5 mm or about 0.7 mm. In some embodiments, a precursor capsule according to the current disclosure has a substantially smooth surface. In some embodiments, a precursor capsule according to the current disclosure has a substantially regular shape with no protrusions or indentations, unless they are necessary for, for example, the functioning of a filling arrangement. A simple shape of a precursor capsule may keep the cost of manufacturing capsules low. However, in some embodiments, a precursor capsule may comprise protrusions extending towards the interior of the precursor space. Such protrusions, which may have a variety of different shapes, may help further increase the precursor or precursor composition surface available for vaporization.

The measurements of a precursor capsule according to the current disclosure depend on the application, precursor and precursor vessel. Thus, the volume of the precursor space, as well as the dimensions of the shell may vary. In some embodiments, a diameter of the shell may vary from about 0.2 cm to about 20 cm. A diameter of the shell may be, for example, from 0.5 cm to 8 cm, from 1 cm to 8 cm, from 2 cm to 8 cm, from 4 cm to 8 cm or from 5 cm to 8 cm. A diameter of the shell may be, for example, from 5 cm to 20 cm, from 7 cm to 20 cm, from 10 cm to 20 cm, from 12 cm to 30 cm or from 15 cm to 20 cm. Thus, the diameter of the shell may be, for example 1 cm, 2 cm, 3 cm, 5 cm, 8 cm, 10 cm, 14 cm, 15 cm, 17 cm or 20 cm.

In some embodiments, the shell has a length and a width, and the length is from about 1 cm to about 20 cm. In smaller scale applications, smaller precursor capsules may be utilized, and the length of the shell of a precursor capsule may be, for example, from about 1 cm to about 8 cm, or from about 3 cm to about 8 cm, or from about 5 cm to about 8 cm, or from about 6 cm to about 8 cm, such as 2 cm, 4 cm or 7 cm. In larger-scale applications, the length of a precursor capsule according to the current disclosure may be, for example, from about 8 cm to about 20 cm, or from about 10 cm to about 20 cm, or from about 12 cm to about 20 cm, or from about 15 cm to about 20 cm, such as 9 cm, 13 cm or 14 cm.

In some embodiments, the shell has a length and a width, and the width is about from about 0.4 cm to about 10 cm. In smaller scale applications, smaller precursor capsules may be utilized, and the width of the shell may be, for example, from about 0.4 cm to about 6 cm, or from about 0.5 cm to about 6 cm, or from about 1 cm to about 6 cm, or from about 2 cm to about 6 cm, or from about 3 cm to about 6 cm, such as 4 cm or 5 cm. In larger-scale applications, the width of a precursor capsule according to the current disclosure may be, for example, from about 5 cm to about 10 cm, or from about 7 cm to about 10 cm, such as 6 cm, 8 cm or 9 cm.

In some embodiments, the precursor space has a volume of from about 1 cm³ to about 20 cm³. For example, the volume of the precursor space may be from about 1 cm³ to about 2 cm³, or from about 1 cm³ to about 5 cm³, or from about 1 cm³ to about 7 cm³, from about 1 cm³ to about 10 cm³, or from about 1 cm³ to about 12 cm³, or from about 1 cm³ to about 15 cm³. In some embodiments, the volume of the precursor space may be, for example, from about 15 cm³ to about 20 cm³, or from about 12 cm³ to about 20 cm³, or from about 10 cm³ to about 20 cm³, or from about 8 cm³ to about 20 cm³, or from about 5 cm³ to about 20 cm³.

The shell of the precursor capsule is vapor-permeable to allow precursor in vapor form to leave the precursor capsule under vaporization conditions. To allow the vaporized precursor to leave the precursor capsule, the shell of the precursor capsule is permeable to a vaporized precursor species. In some embodiments, precursor in vapor form may diffuse through the shell. In some embodiments, precursor in vapor form may move through the shell by mass flow. A precursor capsule according to the current disclosure does not need to block the exit of the liquid or solid precursor or precursor composition completely. The advantages of the current disclosure may be realized even if some amount of liquid or solid precursor or precursor composition leaks out of the precursor vessel. In some embodiments, the shell is configured to substantially retain the liquid or solid precursor in the precursor space. In some embodiments, the shell is configured to retain the liquid or solid precursor in the precursor space. A non-vaporized precursor means a precursor or a precursor composition in liquid or solid phase. In some embodiments, a precursor capsule according to the current disclosure comprises a rigid support structure a vapor permeable portion. The rigid support may be a frame.

In some embodiments, the shell of a precursor capsule comprises openings for vaporized precursor to exit the precursor capsule. An opening may be considered an area devoid or lacking shell material that is discernible from the surrounding areas. A hole may be created at the time the shell material is produced or afterwards by perforating the shell material. The size, amount and location of the openings may vary according to a specific embodiment. The openings may have different shapes. In some embodiments, openings may be circular or substantially circular. In some embodiments, openings may be elliptical. In some embodiments, the openings may be oblong. In some embodiments, the openings may be substantially square. In some embodiments, the openings may be rectangular or substantially rectangular. In some embodiments, the largest cross section of the openings is from about 50 μm to about 5 mm, or from about 100 μm to about 5 mm, or from about 200 μm to about 5 mm, or from about 500 μm to about 5 mm, or from about 1 mm to about 5 mm, or from about 2 mm to about 5 mm, or from about 3 mm to about 5 mm, or from about 4 mm to about 5 mm. In some embodiments, the largest cross section of the openings is from about 50 μm to about 3 mm, or from about 50 μm to about 1 mm, or from about 50 μm to about 500 μm, or from about 50 μm to about 300 μm, or from about 50 μm to about 200 μm, or from about 50 μm to about 100 μm.

To optimize the gas permeability of the shell, the openings may comprise as large proportion of the shell surface area as possible. In some embodiments, vapor permeable area may comprise as large proportion of the shell surface area as possible. In some embodiments, at least 50% of the surface area of the shell is vapor permeable. In some embodiments, at least 60% of the surface area of the shell is vapor permeable. In some embodiments, at least 70% of the surface area of the shell is vapor permeable. In some embodiments, at least 80% of the surface area of the shell is vapor permeable. In some embodiments, at least 90% of the surface area of the shell is vapor permeable. In some embodiments, at least 95% of the surface area of the shell is vapor permeable. In some embodiments, from about 50% to about 99% of the surface area of the shell is vapor permeable. In some embodiments, from about 50% to about 95% of the surface area of the shell is vapor permeable. In some embodiments, from about 50% to about 90% of the surface area of the shell is vapor permeable. In some embodiments, from about 50% to about 85% of the surface area of the shell is vapor permeable. In some embodiments, from about 50% to about 80% of the surface area of the shell is vapor permeable. In some embodiments, from about 50% to about 75% of the surface area of the shell is vapor permeable. In some embodiments, from about 50% to about 70% of the surface area of the shell is vapor permeable. In some embodiments, from about 50% to about 60% of the surface area of the shell is vapor permeable.

However, in some embodiments, a high-volatility precursor may be packed in a precursor capsule according to the current disclosure. In some embodiments, the volatility of a high-volatility precursor is at least 2 Torr under standard conditions. In some embodiments, the volatility of a high-volatility precursor is at least 5 Torr under standard conditions. In some embodiments, the volatility of a high-volatility precursor is at least 10 Torr under standard conditions. In such embodiments, less than about 50% of the surface area of the shell may be vapor permeable. In some embodiments, less than about 30% of the surface area of the shell is vapor permeable. In some embodiments, less than about 20% of the surface area of the shell is vapor permeable. In some embodiments, less than about 10% of the surface area of the shell is vapor permeable. In some embodiments, from about 5% to about 50% of the surface area of the shell is vapor permeable. In some embodiments, from about 5% to about 25% of the surface area of the shell is vapor permeable. In embodiments where the vapor permeable area is less than about 50% of the surface area of the shell, the precursor capsules according to the current disclosure may improve or simplify the regulation of precursor vaporization. Needle valves are often used in the art to regulate volatile precursor flow into a reaction chamber, but a precursor capsule according to the current disclosure may add an additional or alternative means of precursor vapor regulation.

In some embodiments, the shell of a precursor capsule comprises mesh material. In some embodiments, the shell consists essentially of mesh material. In some embodiments, the largest diameter of the openings is smaller than the diameter of particles in a precursor composition.

In some embodiments, the shell comprises vapor movement paths. A shell material may comprise vapor movement paths. A vapor movement path may be considered a route inside the shell material for a precursor in vapor phase to travel between the inside and outside of the shell. A vapor movement paths may be dispersed throughout the shell material. In other words, vapor movement paths may be dispersed throughout the shell material without forming discernible openings in shell material. In some embodiments, a shell comprises fiber material. Fiber material may comprise vapor movement paths. In some embodiments, the shell consists essentially of fiber material. In some embodiments, the shell may comprise gas-permeable film.

By vaporization of a precursor is herein meant the ability of liquid or solid precursor to become vaporized by, for example, evaporation or sublimation, and to be carried outside the precursor capsule for being transported to a reaction chamber of a vapor deposition assembly. By vaporization conditions is herein meant the conditions under which vaporization is intended to take place. For example, vaporization conditions may include a pre-determined temperature and/or pressure range. Outside vaporization conditions, for example during storage or transport of a precursor capsule, or of a precursor vessel containing precursor capsules, the vaporization may or may not take place. Under other conditions than vaporization conditions, the precursor may vaporize more slowly than under vaporization conditions.

The shell of a precursor capsule according to the current disclosure may be manufactured from any material or materials that is/are suitable for being used in a vapor deposition process. The shell material should be inert enough not to release unwanted substances into the vapor deposition process. The shell material should also be able to withstand the targeted vaporization conditions, such as temperature and pressure. The precursor capsule according to the current disclosure may be reusable. Thus, the shell material should be amenable to an industrial cleaning process. For example, metals, such as stainless steel or aluminum may be used as shell material. In some embodiments, metal alloys, such as brass, may be used as shell material. Additionally, vapor deposition compatible plastic types are known in the art, which may be suitable as shell material. Other materials, such as ceramics or composite materials can be envisaged. In some embodiments, the shell material comprises a metal. In some embodiments, the shell material consists essentially of a metal. In some embodiments, the shell material consists essentially of at least two metals. In some embodiments, the shell comprises a coating. Thus, shell material, such as a metal, may be coated with another material. Coating may improve the properties of the precursor capsule, since the surface properties of the shell may be optimized by a coating, while the shell material may be selected based on its structural properties.

In some embodiments, the shell is constructed and arranged to be openable to allow the filling of precursor into the precursor capsule. The shell may contain a filling opening that may be closable by a plug or a lid. In some embodiments, the shell is constructed from parts that are moveable relative to each other for opening the precursor capsule. For example, the shell may comprise two detachable parts. The detachable parts may be configured to remain together when brought in contact with each other. Examples of such attachments may be various snap joints, closely matching attachment surfaces, and the like. Two parts of a shell may be connected by a hinge.

A precursor capsule according to the current disclosure may be filled with variable amounts of precursor composition. The amount of precursor composition in the precursor capsule depends on the volume of the precursor space, density of the composition, as well as on the desired degree of filling of the precursor capsule. For example, in some embodiments, a precursor capsule according to the current disclosure may be filled with from about 0.5 g to about 50 g of precursor or precursor composition. In some embodiments, for example, about 1 g, 5 g, 10 g, 12 g, 15 g, 20 g, 25 g, 30 g or 40 g of precursor composition may be loaded into the precursor capsule. However, larger amounts of precursor composition may be packed in a precursor capsule in higher volume applications.

In some embodiments, it may not be necessary, or desired, to completely fill a precursor capsule. For example, a precursor capsule may be filled to about 50%, 60%, 70%, 80% or 90% of the volume of the precursor space.

In an aspect, a precursor vessel containing at least two precursor capsules according to the current disclosure is disclosed. A chemical reactant delivery system for vapor deposition can include a liquid or solid precursor vessel for providing a reactant into a reaction chamber. The reactant delivery system may comprise a heating means including a heater, such as a radiant heat lamps, resistive heaters etc. In some embodiments, the heating means may be adapted to heat the precursor vessel to a temperature from about 20° C. to about 500° C., such as to about 50° C., 70° C., 100° C., 200° C., 250° C., 300° C., 350° C. or 400° C.

The precursor vessel according to the current disclosure includes at least two precursor capsules for holding a precursor for a vapor deposition process. The heater may heat up the vessel to vaporize the precursor in the vessel. The precursor vessel can have an inlet and an outlet for the flow of a carrier gas (e.g., N₂) through the precursor vessel. The carrier gas may be an inert gas. The carrier gas may sweep precursor vapor, for example sublimated or evaporated precursor, along with it through the vessel outlet and ultimately to a substrate in a reaction chamber. The precursor vessel typically includes isolation valves for fluidly isolating the contents of the vessel from the vessel exterior. One isolation valve may be provided upstream of the vessel inlet, and another isolation valve may be provided downstream of the vessel outlet. The precursor vessel of some embodiments comprises, consists essentially of, or consists of a sublimator.

Depending on the application, the composition may be heated and/or maintained at very low pressures to produce a sufficient amount of precursor vapor for the vapor deposition process. Precursor vessels may be supplied with gas lines extending from the inlet and outlet, isolation valves on the lines, and fittings on the valves, the fittings being configured to connect to the gas flow lines of the remaining vapor deposition assembly. It is often desirable to provide a number of additional heaters for heating the various valves and gas flow lines between the precursor vessel and the reaction chamber, to prevent the precursor vapor from condensing and depositing on such components. Accordingly, the gas-conveying components between the precursor vessel and the reaction chamber are sometimes referred to as a “hot zone” in which the temperature is maintained above the vaporization/condensation/sublimation temperature of the precursor.

In some embodiments, a precursor vessel according to the current disclosure is configured and arranged for use in a vapor deposition assembly. In some embodiments, precursor vessel according to the current disclosure is constructed and arranged to operate at a vaporization temperature of about 30° C. to about 500° C., and material of the precursor capsule shell is selected to withstand said vaporization temperature. In some embodiments, precursor vessel according to the current disclosure is constructed and arranged to operate at a vaporization temperature of about 200° C. to about 500° C., and material of the precursor capsule shell is selected to withstand said vaporization temperature. In some embodiments, precursor vessel according to the current disclosure is constructed and arranged to operate at a vaporization temperature of about 300° C. to about 500° C., and material of the precursor capsule shell is selected to withstand said vaporization temperature. In some embodiments, precursor vessel according to the current disclosure is constructed and arranged to operate at a vaporization temperature of about 400° C. to about 500° C., and material of the precursor capsule shell is selected to withstand said vaporization temperature. In some embodiments, precursor vessel according to the current disclosure is constructed and arranged to operate at a vaporization temperature of about 30° C. to about 200° C., and material of the precursor capsule shell is selected to withstand said vaporization temperature. In some embodiments, precursor vessel according to the current disclosure is constructed and arranged to operate at a vaporization temperature of about 50° C. to about 150° C., and material of the precursor capsule shell is selected to withstand said vaporization temperature. In some embodiments, precursor vessel according to the current disclosure is constructed and arranged to operate at a vaporization temperature of about 70° C. to about 150° C., and material of the precursor capsule shell is selected to withstand said vaporization temperature.

In still another aspect, a vapor deposition assembly comprising a precursor vessel containing at least two precursor capsules according to the current disclosure is disclosed. The vapor deposition assembly includes a reaction chamber for performing a vapor deposition process, and a precursor delivery system comprising a precursor vessel containing the precursor capsules according to the current disclosure connected to the reaction chamber to supply a precursor into the reaction chamber.

The vapor deposition assembly comprises one or more reaction chambers constructed and arranged to hold a substrate and a precursor injector system constructed and arranged to provide a precursor into the reaction chamber in a vapor phase. The vapor deposition assembly further comprises a precursor vessel containing at least two precursor capsules according to the current disclosure and the assembly is constructed and arranged to provide a composition according to the current disclosure via the precursor injector system to the reaction chamber to deposit group 13 metal—containing material on the substrate.

In some embodiments, the vapor deposition assembly may additionally include control processors and software configured to operate the reaction chamber to perform an ALD process. In some embodiments, the vapor deposition assembly may additionally include control processors and software configured to operate the reaction chamber to perform a CVD process.

In one aspect, a method of loading a precursor into a precursor vessel is disclosed. The method comprises providing precursor capsules for holding a precursor for a vapor deposition process containing a precursor composition, and inserting at least two precursor capsules into the precursor vessel; wherein the precursor capsules comprise a shell configured to define a precursor space, and wherein the shell is vapor permeable to allow precursor in vapor form to leave the precursor capsule under vaporization conditions.

The precursor may be loaded into an openable precursor capsule by any of the means described above. For example, if the precursor capsule comprises a filling opening, precursor or precursor composition may be loaded through it. The opening may be closed with a lid or a plug. In some embodiments, a part of a shell may be removed or two parts of the precursor capsule may be moved relative to each other for filling the precursor capsule. In embodiments comprising vapor-permeable films, the precursor capsule may be sealed after precursor or precursor composition has been inserted into the precursor capsule.

A precursor capsule may be stored after precursor or precursor composition has been loaded into the precursor capsule. The storage conditions and acceptable duration of storage depend on the precursor chemistry. When the precursor or precursor composition is to be inserted into a precursor vessel, the vessel is opened and a desired amount of precursor capsules is inserted into the precursor vessel. Then, the precursor vessel is closed. The filled precursor vessel may be stored, shipped further or connected to a vapor deposition assembly.

### DETAILED DESCRIPTION OF THE DRAWINGS

The disclosure is further explained by the following exemplary embodiments depicted in the drawings. The illustrations presented herein are not meant to be actual views of any particular precursor capsule or a vessel, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The embodiments depicted in the drawings may contain additional elements and details, which may be omitted for clarity.

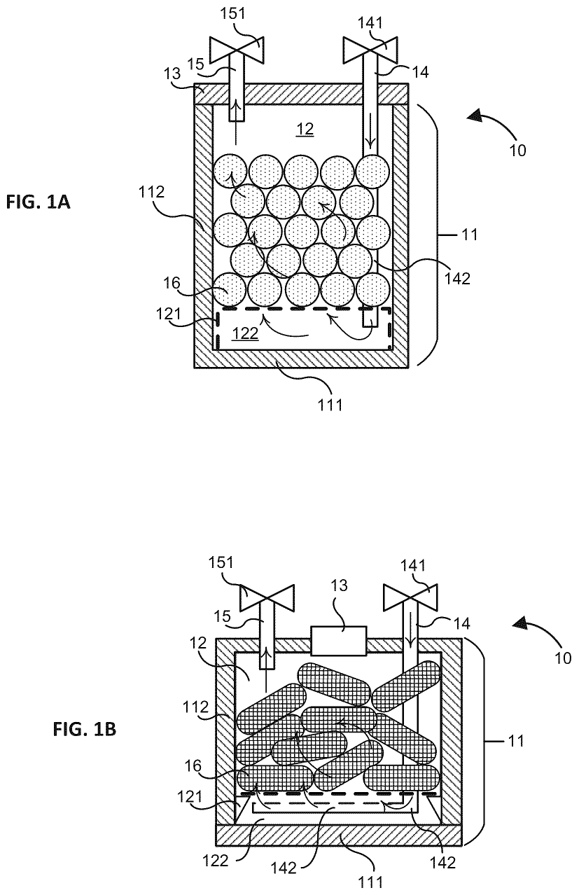

FIG. 1A illustrates a precursor vessel 10 according to the current disclosure as a schematic section along its longitudinal axis. The vessel 10 is fabricated of a suitable vessel material, such as stainless steel, aluminum, copper, nickel, silver, their alloys, graphite, boron nitride, ceramic material or a combination or a mixture of said materials. The precursor vessel 10 material may be heat-conducting material. The precursor vessel 10 material may be coated or clad material.

The precursor vessel comprises a housing 11 defining an interior volume 12 of the precursor vessel 10. The housing 11 comprises a bottom 111, and a sidewall 112. In some embodiments, the housing 11 has a substantially circular cylindrical shape. Thus, the housing 11 has a circular bottom 111. However, the precursor vessel 10 can have any shape that is compatible with an appropriate flow of carrier gas through the interior volume 12 thereof. In some embodiments, the precursor vessel 10 has substantially a shape of rectangular prism. The shape of the precursor vessel 10 may deviate from the above-mentioned ideal geometrical shapes due to usability, ease of manufacture and handling. For example, any edges and/or corners may be rounder, or some sides at least partially slanted. In some embodiments, a bottom and a sidewall may not be discernable. The bottom 111 may be curved. The housing 11 may be constructed from one part by, for example, machining. However, it is possible that the housing 11 is formed from two or more parts attached to each other in a gas-tight manner. For example, the bottom 111 and the sidewall 112 may be separable components.

In the embodiment of FIG. 1A, the precursor vessel 10 comprises a lid 13 for isolating the interior volume 12 from the surrounding atmosphere together with the housing 11. The lid 13 may comprise an inlet 14 for feeding carrier gas into the precursor vessel 10. The inlet 14 may comprise an inlet valve 141, and the inlet 14 may be arranged to introduce carrier gas into the interior volume 12 of the precursor vessel 10, when the inlet valve 141 is open. In the embodiment of FIG. 1A

The lid 13 may comprise an outlet 15 for feeding carrier gas and a vaporized precursor into a reaction chamber of a vapor deposition assembly (not shown). The outlet 15 may comprise an outlet valve 151 and be arranged to release carrier gas containing vaporized precursor into reaction chamber when the outlet valve 151 is open. When connected to a vapor deposition assembly, gas lines may extend from the inlet 14 and outlet 15, isolation valves on the lines, and fittings on the valves, the fittings being configured to connect to the gas flow lines of the remaining vapor deposition assembly.

The size and proportions of the precursor vessel 10 may vary according to design choices and application in question, as well as due to scale of vapor deposition process. In some embodiments, the height of the precursor vessel 10 is larger than its width. In some embodiments, the height of the precursor vessel 10 is equal to its width. In some embodiments, the height of the precursor vessel 10 is smaller than its width. In some embodiments, the precursor vessel 10 may have a height to width aspect ratio in the range of about 0.5 to 4, for example 1 to 2 or 1 to 3. The height of the precursor vessel 10 is the outside measurement of the precursor vessel 10 from the lid 13 to the portion of the housing 11 furthest away from the lid 13. The width of the precursor vessel 10 is the longest measurement across the precursor vessel 10 perpendicular to the height.

The interior volume 12 of the precursor vessel 10 is adapted for holding precursor capsules 16 according to the current disclosure. The interior volume 12 comprises a capsule support 121. The capsule support 121 is a gas-permeable structure on which the precursor capsules according to the current disclosure are positioned. The capsule support 121 may define a lower gas space 122 below the part of the interior volume 12 containing the precursor capsules 16 according to the current disclosure. The capsule support 121 may, for example, distribute carrier gas entering the internal volume 12 along the surface area of the bottom 111 of the precursor vessel 10 in the lower gas space 122. This may improve the uniformity of the gas flow through the precursor vessel 10. The capsule support 121 may be manufactured from the same material as the precursor vessel. The capsule support 121 may comprise a metal net or mesh. The capsule support 121 may be a plate with holes. The capsule support 121 may be a freely standing structure or removably attached to the wall 112 or the bottom 111 of the precursor vessel 10. In some embodiments, the capsule support 121 may be permanently attached to the precursor vessel housing 11. In the embodiment of FIG. 1A, an inlet tube 142 extends from the outlet 14 in the lid 13 to the lower gas space 122 to deliver carrier gas into the lower gas space 122.

The arrows in FIG. 1A indicate the movement of a carrier gas through the precursor vessel 10. The carrier gas enters the interior volume 12 through the inlet tube 142. The carrier gas is distributed, at least to some extent, in the lower gas space 122. The carrier gas moves out of the lower gas space 122 through openings in the capsule support 121. A precursor present in the precursor capsules 16 is vaporized and carried by carrier gas towards the outlet 15. The precursor capsules 16 according to the current disclosure depicted in FIG. 1A, have a spherical shape. The carrier gas may travel partially inside and partially outside of the precursor capsules 16. In some embodiments, it may be advantageous to minimize the volume outside the precursor capsules. In such embodiments, the precursor capsules 16 may be tightly packed, and contain straight surfaces to allow packing the precursor capsules 16 tightly in the internal volume 12 of the precursor vessel. Carrier gas and vaporized precursor leave the precursor vessel 19 through the outlet 15.

The precursor vessel 10 may be coupled to heating means, such as a heater, for example radiant heat lamps or resistive heaters. The heating means heats up the precursor vessel 10 to enhance the vaporization of a precursor in the precursor vessel 10. The heating means may be internal or external to the precursor vessel 10.

The precursor vessel 10 may comprise additional features that are omitted from the figure for clarity. For example, the precursor vessel 10 may comprise precursor distribution means for enabling efficient precursor vaporization. To this end, various precursor holding structures or carrier gas guiding arrangements may be present in the interior volume 12 of the precursor vessel 10. The precursor vessel 10 may comprise features for avoiding solid precursor particles from being caught in the carrier gas stream. Various filters or other entrapment structures may be used. Additionally, the inlet 14 and the outlet 15, as well as gas lines extending therefrom may comprise heaters for heating the various valves and gas lines between the precursor vessel 10 and the reaction chamber to prevent the precursor vapor from condensing and depositing on any components.

FIG. 1B illustrates another embodiment of a precursor vessel 10 according to the current disclosure. The embodiment of FIG. 1B comprises analogous features to those described for FIG. 1A. However, in the embodiment of FIG. 1B, the housing 11 comprises the bottom 111, wall 112, as well as a majority of the upper surface of the precursor vessel 10, which was covered by a lid in FIG. 1A. In the embodiment of FIG. 1B, the precursor vessel 10 comprises a cap or a plug 13 for inserting and removing a precursor into, or out of the precursor vessel 10, respectively. The cap 13 may comprise various structural, closing and security features available in the art of closing vessels with a pressure differing from the ambient pressure. Further, the bottom 111 in FIG. 1B is a separable component from the walls, whereas in FIG. 1A, the bottom 111 and the wall 112 where one piece.

The inlet tube 142 in FIG. 1B extends further into the lower gas space 122. It extends substantially parallel to the bottom 111 of the precursor vessel 10, and contains gas exit holes, through which carrier gas may be released into the lower gas space 122. In the figure, the inlet tube 142 comprises a single tube. However, in some embodiments, the portion of the inlet tube 142 extending substantially parallel to the bottom 111 may comprise several branches. The portion may alternatively be ring-shaped. In some embodiments comprising a portion of the inlet tube 142 extending substantially parallel to the bottom 111 it may be possible to omit a separate capsule support 121.

Whereas the embodiment of FIG. 1A comprises a capsule support 121 standing at the bottom 111 of the precursor vessel 10, in the embodiment of FIG. 1B, the capsule support 121 rests on a ledge or ledges mounted on the wall 112 of the precursor vessel 10.

The precursor capsules 16 of FIG. 1B are substantially spherocylindrical. Thus, the shell of a precursor capsule 16 comprises a cylindrical middle portion, and a spherical end on each side of the middle portion. Similarly to FIG. 1A, arrows inside the precursor vessel 10 indicate flow possible directions of a carrier gas and vaporized precursor.

FIG. 1C illustrates yet another embodiment of a precursor vessel 10 according to the current disclosure. This embodiment is similar to that of FIG. 1A, containing a housing 11, bottom 111, and a sidewall 112. The vessel comprises a lid 13 with and an inlet 14, and an outlet 15, as well as the respective inlet valve 141 and outlet valve 151. An inlet tube 142 extends from the outlet 14 in the lid 13 to the vicinity of the bottom 111 of the precursor vessel. In the embodiment of FIG. 1C, a capsule support 121 is formed as several surfaces defining a tortuous flow path through the interior volume 12. The flow path begins at the end of the inlet tube 142 extending the length that a carried gas travels inside the precursor vessel, as indicated by the arrows in FIG. 1C. Such structure may improve the vaporization of low vapor-pressure precursors.

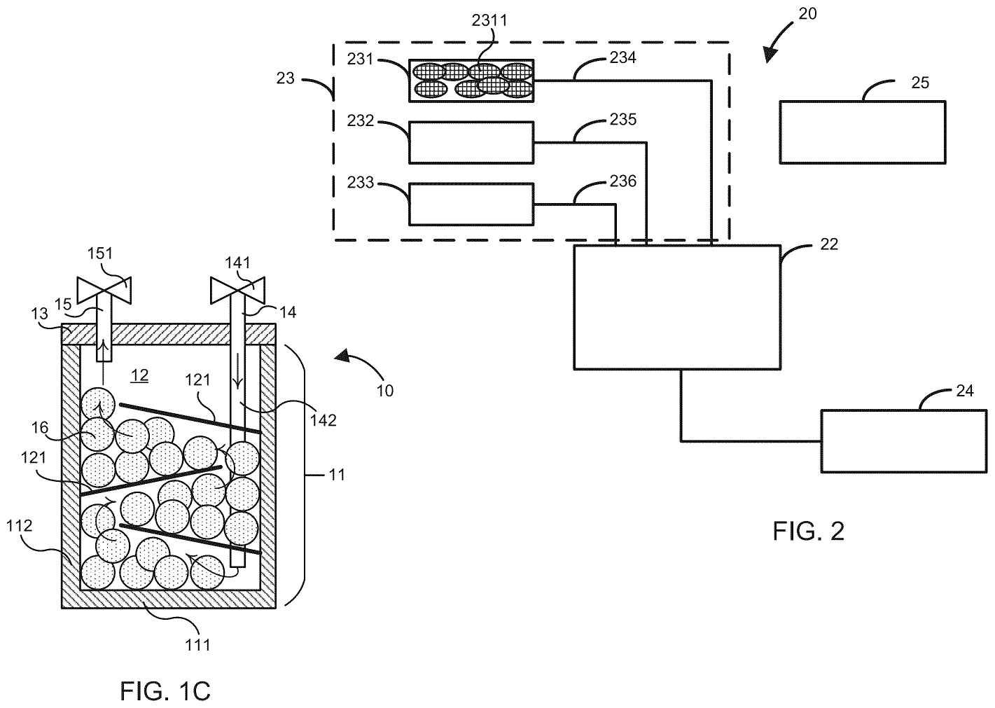

FIG. 2 illustrates a vapor deposition assembly 20 comprising a precursor vessel 231 according to the current disclosure in a schematic manner. The deposition assembly 20 can be used to perform a vapor deposition process. The vapor deposition process may be, for example, a CVD-type process or an ALD-type process or a hybrid thereof. In the illustrated example, deposition assembly 20 includes one or more reaction chambers 22, a precursor injector system 23 and a precursor vessel 231 containing at least two precursor capsules 2311 for holding a precursor for a vapor deposition process. The vapor deposition assembly 20 further comprises a second precursor vessel 232, a purge gas source 233, an exhaust source 24, and a controller 25.

Reaction chamber 22 can include any suitable reaction chamber, such as an ALD or CVD reaction chamber.

The precursor vessel 231 can include a vessel and precursor capsules 2311 as described herein. A second precursor vessel 232 can include a vessel and one or more additional precursors-alone or mixed with one or more carrier gases. Purge gas source 233 can include one or more inert gases, such as N₂ or He or Ar. Although illustrated with three source/precursor vessels 231-233, deposition assembly 20 can include any suitable number of source/precursor vessels. Source/precursor vessels 231-233 can be coupled to reaction chamber 22 via lines 234-236, which can each include flow controllers, valves, heaters, and the like. In some embodiments, composition according to the current disclosure in the precursor vessel 231, and/or second precursor and/or purge gas may be heated. In some embodiments, the precursor vessel 231 is heated so that the composition according to the current disclosure reaches a temperature between about 50° C. and about 140° C., such as between about 70° C. and about 130° C., for example 60° C., 80° C., 90° C., 100° C., 110° C. or 120° C. Exhaust source 24 can include one or more vacuum pumps.

Controller 25 includes electronic circuitry and software to selectively operate valves, manifolds, heaters, pumps and other components included in the deposition assembly 20. Such circuitry and components operate to introduce precursors, reactants and purge gases from the respective sources 231-233. Controller 25 can control timing of gas pulse sequences, temperature of the substrate and/or reaction chamber 22, pressure within the reaction chamber 22, and various other operations to provide proper operation of the deposition assembly 20. Controller 25 can include control software to electrically or pneumatically control valves to control flow of precursors, reactants and purge gases into and out of the reaction chamber 22. Controller 25 can include modules such as a software or hardware component, which performs certain tasks.

Other configurations of deposition assembly 20 are possible, including different numbers and kinds of precursor and reactant sources and purge gas sources. Further, it will be appreciated that there are many arrangements of valves, conduits, precursor sources, and purge gas sources that may be used to accomplish the goal of selectively and in coordinated manner feeding gases into reaction chamber 22. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 20, substrates, such as semiconductor wafers (not illustrated), are transferred from, e.g., a substrate handling system to reaction chamber 22. Once substrate(s) are transferred to reaction chamber 22, one or more gases from gas sources 231-233, such as precursors, reactants, carrier gases, and/or purge gases, are introduced into reaction chamber 22.

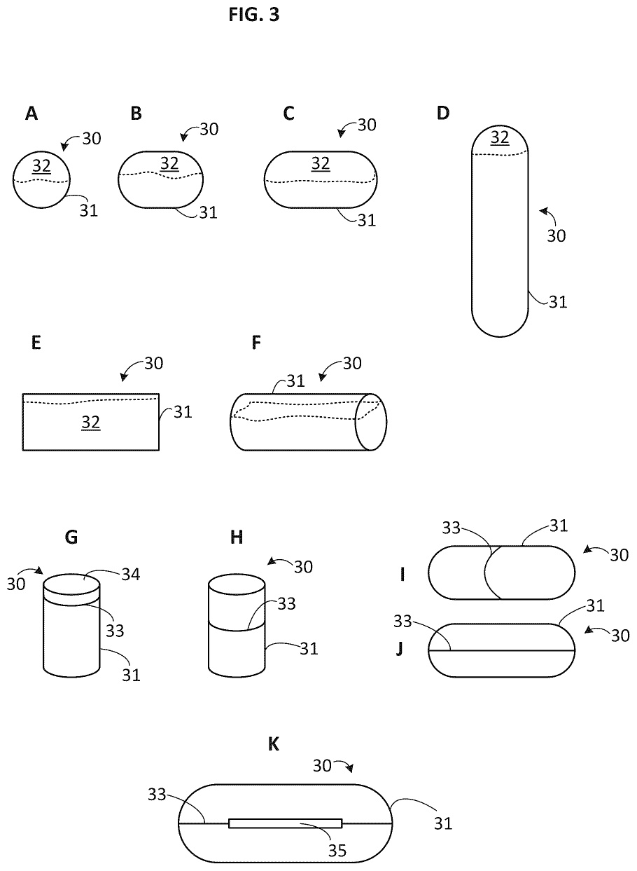

FIG. 3 depicts embodiments of the precursor capsule 30 according to the current disclosure. In panels A to K, the shell is indicated by numeral 31, and the precursor space with numeral 32. The dotted line in panels A to F illustrates a possible fill level of a precursor or precursor composition. The initial fill level after packing of a precursor or a precursor composition into a capsule according to the current disclosure may vary according to, for example, precursor properties, application and quantity used in a given situation, and may be determined based on practical and economic considerations.

Panels A to D illustrate longitudinal sections of precursor capsules 30. Panel A presents a spherical precursor capsule according to the current disclosure. Thus, the length and width of the precursor capsule of this embodiment are equal. Panels B to D illustrate gradually more elongated embodiments of the precursor capsule 30, in which the width to length ratio is approximately 1:1.5 (panel B), 1:2 (panel C) or 1:3.7 (panel D). In some embodiments, width to length ratio may be, for example, 1:5, 1:6, 1:8 or 1:10. The cross section of a precursor capsule in the examples of FIG. 3 may be circular. However, in some embodiments, the precursor capsule 30 may have an elliptical or an angular, such as quadrangular, pentagonal or hexagonal, cross section. Panel E depicts a side view of a cylindrical embodiments of a precursor capsule 30. In panel F, a cylindrical precursor capsule 30 is depicted as an axonometric view.

Panels G to K depict some possible structural options for a precursor capsule 30. In the embodiments of panels G to K, the precursor capsule 30 is openable. The precursor capsules 30 of panels G to K comprise two parts that can be joined to each other at a junction 33. In panel G, one of the parts may be considered a cap 34, whereas in panel H, the two parts of the precursor capsule 30 are of equal size. Thus, in the embodiment of panel H, no cap part is specified. The junction 33 may comprise various attachment means (not shown), such as snap joints complementary grooves and the like, to hold the two parts of the precursor capsule 30 together.

Panels I and J of FIG. 3 exemplify the possibility for the two parts of a capsule to be oriented in variable ways. In pane I the junction 33 is positioned cross-wise relative to the length of the capsule 30. In panel J, the junction 33 is positioned along the length of the capsule 30. In panel K, an embodiment of a precursor capsule 30 is depicted, in which the two parts of the capsule 30 are held together by a hinge 35. In some embodiments, the two parts of a precursor capsule 30 are detachable from each other.

Although panels G to K depict only embodiments in which the precursor capsule 30 comprises two parts, a precursor capsule 30 may be made up from more parts. In most embodiments, however, a capsule comprising two parts is most likely to be a cost-effective and easy to use option. Even if a capsule according to the current disclosure is openable in two parts, each of the parts may be made up of more than one element that have been attached to each other in an inseparable way.

1. A precursor vessel comprising:
a housing comprising an interior volume;
a capsule support within the interior volume; and
one or more precursor capsules for holding a precursor for a vapor deposition process.

2. The precursor vessel of claim 1, wherein the one or more precursor capsules each comprise a shell configured to define a precursor space, and wherein the shell is vapor-permeable to allow precursor in vapor form to leave the precursor capsule under vaporization conditions.

3. The precursor vessel of claim 1, wherein the capsule support is gas permeable.

4. The precursor vessel of claim 1, wherein the capsule support defines a lower gas space below a part of the interior volume containing the one or more precursor capsules.

5. The precursor vessel of claim 4, wherein the lower gas space receives and distributes a carrier gas.

6. The precursor vessel of claim 1, wherein the capsule support comprises a metal net or mesh.

7. The precursor vessel of claim 1, wherein the capsule support comprises a metal plate with holes.

8. The precursor vessel of claim 1, wherein the housing comprises a lid comprising a fluid inlet and a fluid outlet.

9. The precursor vessel of claim 8, further comprising an inlet tube that extends from the lid to a lower gas space below a part of the interior volume containing the one or more precursor capsules.

10. The precursor vessel of claim 9, wherein the inlet tube comprises a section that extends substantially parallel to a bottom of the precursor vessel.

11. The precursor vessel of claim 9, wherein the inlet tube comprises a plurality of gas exit holes.

12. The precursor vessel of claim 9, wherein the capsule support comprises a section of the inlet tube.

13. The precursor vessel of claim 8, wherein the lid comprises a cap.

14. The precursor vessel of claim 1, further comprising a ledge within the interior volume, wherein the capsule support rests on the ledge.

15. A precursor vessel comprising:
a housing comprising an interior volume;
one or more precursor capsules for holding a precursor for a vapor deposition process; and
a lower gas space below a part of the interior volume containing the precursor capsules.

16. The precursor vessel of claim 15, wherein the one or more precursor capsules each comprise a shell configured to define a precursor space, and wherein the shell is vapor-permeable to allow precursor in vapor form to leave the precursor capsule under vaporization conditions.

17. The precursor vessel of claim 15, comprising one or more capsule supports.

18. The precursor vessel of claim 15, comprising a plurality of capsule supports defining a tortuous path.

19. The precursor vessel of claim 18, further comprising an inlet tube extending to an area beneath the plurality of capsule supports.

20. A vapor deposition assembly comprising the precursor vessel of claim 18.
